(19) United States
(12) Patent Application Publication
(10) Pub. No.: US 2022/0059629 A1
(43) Pub. Date: Feb. 24, 2022

(54) DISPLAY DEVICE

(71) Applicant: Samsung Display Co., LTD., Yongin-si (KR)

(72) Inventors: Soo Hyun PARK, Seoul (KR); Dong Hoon KWAK, Hwaseong-si (KR); Dong Hyun KIM, Hwaseong-si (KR); Seul Gi HAN, Suwon-si (KR)

(21) Appl. No.: 17/399,223

(22) Filed: Aug. 11, 2021

(30) Foreign Application Priority Data
Aug. 19, 2020 (KR) 10-2020-0103816

(51) Int. Cl. H01L 27/32

(52) U.S. Cl. CPC H01L 27/3246; H01L 27/3216

(57) ABSTRACT

A display device includes a substrate, a first pixel electrode disposed on the substrate, and including a first region and a second region electrically connected to each other without overlapping each other, a pixel defining layer disposed on the substrate on which the first pixel electrode is disposed, the pixel defining layer defining a first opening penetrating the pixel defining layer in a thickness direction and exposing the first region of the first pixel electrode, and a second opening penetrating the pixel defining layer in the thickness direction, exposing the second region of the first pixel electrode and separated from the first opening, and a light emitting layer disposed in the first opening exposing the first region of the first pixel electrode and the second opening exposing the second region of the first pixel electrode.

This application claims priority to Korean Patent Application No. 10-2020-0103816 filed on Aug. 19, 2020, and all the benefits accruing therefrom under 35 U.S.C. § 119, the content of which in its entirety is herein incorporated by reference.

### BACKGROUND

### 1. Field

Embodiments of the invention relate to a display device.

### 2. Description of the Related Art

An importance of display devices is being steadily increased with a development of multimedia technology. Accordingly, various types of display devices such as a liquid crystal display (“LCD”) device, an organic light emitting display (“OLED”) device and the like have been used.

Among the display devices, a self-light emitting display device includes a self-light emitting element such as an organic light emitting diode. The self-light emitting element may include two opposite electrodes and a light emitting layer interposed therebetween. In a case of using the organic light emitting diode as the self-light emitting element, electrons and holes from the two electrodes are recombined in the light emitting layer to produce excitons, which transition from an excited state to a ground state, emitting light.

Such a self-light emitting display device is attracting attention as a next-generation display device because of being able to meet a desire for high display quality such as wide viewing angle, high brightness and contrast, and quick response speed as well as being able to be made having a low power consumption, lightweight, and thin due to no necessity of a separate power source.

### SUMMARY

Embodiments of the invention provide a display device in which uniformity of an organic light emitting layer disposed in a pixel (or sub-pixel) is improved and a method of fabricating the display device.

However, the invention is not restricted to the one set forth herein. The above and other embodiments of the invention will become more apparent to one of ordinary skill in the art to which the invention pertains by referencing the detailed description of the invention given below.

An embodiment of a display device includes a substrate, a first pixel electrode disposed on the substrate, and including a first region and a second region electrically connected to each other without overlapping each other, a pixel defining layer disposed on the substrate on which the first pixel electrode is disposed and defining a first opening penetrating the pixel defining layer in a thickness direction and exposing the first region of the first pixel electrode, and a second opening penetrating the pixel defining layer in the thickness direction, exposing the second region of the first pixel electrode, and separated from the first opening, and a light emitting layer disposed in the first opening exposing the first region of the first pixel electrode and the second opening exposing the second region of the first pixel electrode.

An embodiment of a display device includes a substrate, an anode conductive layer disposed on the substrate, a pixel defining layer disposed on the substrate on which the anode conductive layer is disposed, the pixel defining layer defining a first opening, a second opening, a third opening, and a fourth opening penetrating the pixel defining layer in a thickness direction and respectively exposing different regions of the anode conductive layer, and a light emitting layer disposed in the first opening, the second opening, the third opening, and the fourth opening exposing different regions of the anode conductive layer, where, in a plan view, the first opening, the second opening, the third opening, and the fourth opening have a first width that is a width in a first direction and a second width that is a width in a second direction perpendicular to the first direction, and the first width is in a range of about 0.8 times to about 1.2 times the second width.

An embodiment of a display device includes a plurality of first sub-pixels, a plurality of second sub-pixels, a plurality of third sub-pixels, and a plurality of fourth sub-pixels, where the first sub-pixel, the second sub-pixel, and the third sub-pixel emit light of different colors, and the fourth sub-pixel emit light of the same color as the third sub-pixel, where the plurality of first sub-pixels and the plurality of second sub-pixels are alternately arranged along a first direction and form first rows, the plurality of third sub-pixels and the plurality of fourth sub-pixels are alternately arranged along the first direction and form second rows, and the first rows and the second rows are alternately arranged, where the plurality of first sub-pixels and the plurality of third sub-pixels are alternately disposed along a second direction perpendicular to the first direction and form first columns, the plurality of second sub-pixels and the plurality of fourth sub-pixels are alternately disposed along the second direction and form second columns, and the first columns and the second columns are alternately arranged, where each of the plurality of first sub-pixels includes a first emission area, each of the plurality of second sub-pixels includes a second emission area, each of the plurality of third sub-pixels includes a third emission area, and each of the plurality of fourth sub-pixels includes a fourth emission area, and where the first emission area, the second emission area, the third emission area, and the fourth emission area have the same shape in a plan view.

By improving the uniformity of the organic light emitting layer disposed in the pixel (or sub-pixel), it is possible to provide a display device with improved light emission efficiency and uniformity of luminance and a method of fabricating the display device.

### BRIEF DESCRIPTION OF THE DRAWINGS

The above and other embodiments and features of the invention will become more apparent by describing in detail embodiments thereof with reference to the attached drawings, in which:

FIG. 1 is a plan view of an embodiment of a display device;

FIG. 2 is a cross-sectional view taken along line II-II′ of FIG. 1;

FIG. 3 is a schematic plan view showing an embodiment of an arrangement of a plurality of pixels of a display device;

FIG. 4 is an enlarged view of one pixel of FIG. 3;

FIG. 5 is a graph showing uniformity of an embodiment of a light emitting layer of a display device;

FIG. 6 is a cross-sectional view of an embodiment of a display device;

FIGS. 7 to 8 are cross-sectional views illustrating an embodiment of a method of manufacturing a display device;

FIG. 9 is an enlarged view of another embodiment of one pixel of a display device;

FIG. 10 is a cross-sectional view taken along line X-X′ of FIG. 9; and

FIG. 11 is an enlarged view of one pixel of another embodiment of a display device.

### DETAILED DESCRIPTION

Embodiments of the invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached drawing figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the invention, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. In an embodiment, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments will be described in detail with reference to the accompanying drawings.

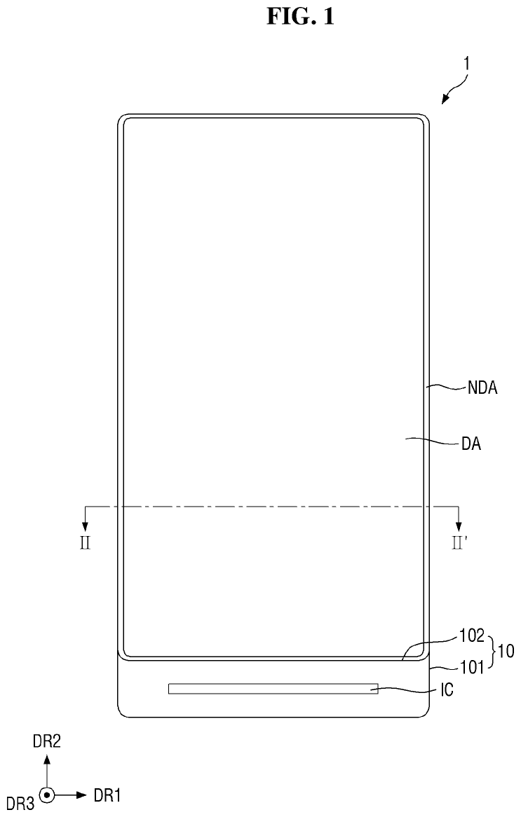

FIG. 1 is a plan view of an embodiment of a display device.

In the embodiments, a first direction DR1 and a second direction DR2 represent different directions crossing each other, for example, directions crossing at a right angle in a plan view. A third direction DR3 indicates a direction intersecting the plane defined by the first direction DR1 and the second direction DR2 and indicates a direction perpendicularly intersecting both the first direction DR1 and the second direction DR2, for example. In the illustrated drawing, the first direction DR1 indicates a horizontal direction of a display device 1, the second direction DR2 indicates a vertical direction of the display device 1, and the third direction DR3 indicates a thickness direction of the display device 1.

In addition, unless otherwise defined, with respect to the third direction DR3, the terms “above,” “top surface,” and “upper side” as used herein refer to a display surface's side of a display panel 10, and the terms “below,” “bottom surface,” and “lower side” as used herein refer to a side opposite to the display surface of the display panel 10. It should be understood, however, that a direction mentioned in the embodiment refers to a relative direction and the embodiment is not limited to the direction mentioned.

Referring to FIG. 1, a display device 1 displays a moving image or a still image. A main screen display direction may be one side of the third direction DR3 (e.g., top emission type display device), but is not limited thereto.

The display device 1 may refer to any electronic device providing a display screen.

Examples of the display device 1 may include a television, a laptop computer, a monitor, a billboard, an internet-of-things (“IoT”) device and the like as well as portable electronic devices such as a mobile phone, a smartphone, a tablet personal computer (“PC”), an electronic watch, a smart watch, a watch phone, a mobile communication terminal, an electronic notebook, an electronic book, a portable multimedia player (“PMP”), a navigation device, a game machine, a digital camera, which provide a display screen.

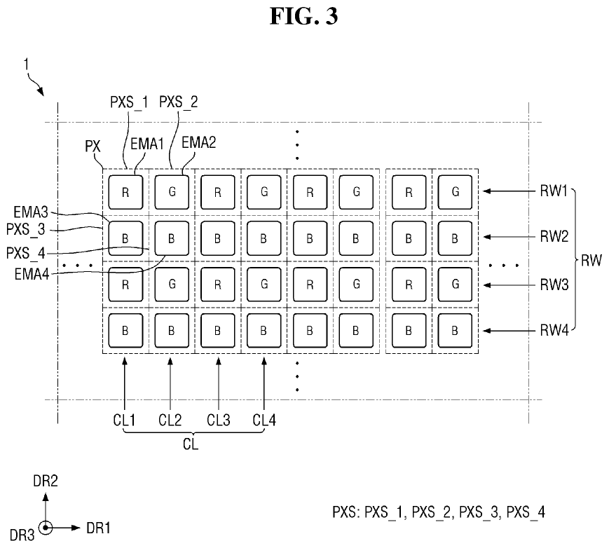

The display device 1 includes a display area DA and a non-display area NDA. The display area DA may be defined as an area displaying a screen, and the non-display area NDA may be defined as an area not displaying a screen. When the display device 1 has a touch function, a touch area, which is an area where a touch input is sensed, may overlap the display area DA, but is not limited thereto. The display area DA may include a plurality of pixels (refer to ‘PX’ in FIG. 3). A description thereof will be given later.

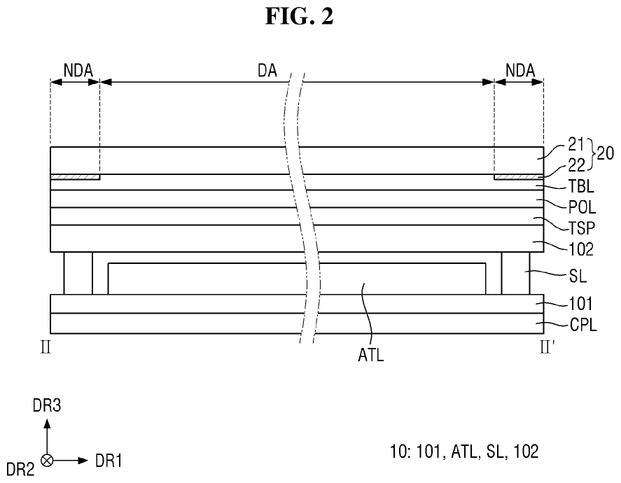

The non-display area NDA is disposed around the display area DA. The non-display area NDA may be a bezel area. The non-display area NDA may overlap a printed layer (refer to ‘22’ in FIG. 2) of a window member (refer to ‘20’ in FIG. 2) to be described later.

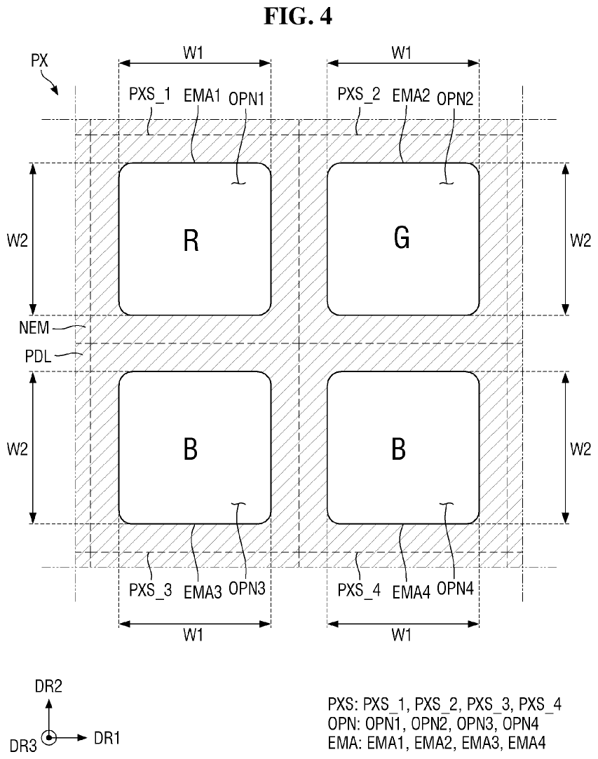

The non-display area NDA may surround all sides (four sides in FIG. 4) of the display area DA. However, the invention is not limited thereto, and the non-display area NDA may not be disposed near an upper side of the display area DA, for example.

In the non-display area NDA, signal lines or driving circuits for applying a signal to the display area DA (and/or the touch area) may be disposed. In an embodiment, a driving chip IC may be disposed in the non-display area NDA. The driving chip IC may include an integrated circuit for driving the display panel 10. The integrated circuit may include an integrated circuit for display and/or an integrated circuit for a touch member (refer to ‘TSP’ in FIG. 2). The driving chip IC may be directly disposed (e.g., mounted) on a region where a first substrate 101 protrudes with respect to a second substrate 102.

Hereinafter, a cross-sectional structure of the display device 1 will be described with further reference to FIG. 2.

FIG. 2 is a cross-sectional view taken along line II-II′ of FIG. 1. FIG. 2 is a schematic cross-sectional view of an embodiment of a display device.

The display device 1 includes a display panel 10 that provides a display screen, a touch member TSP, an anti-reflection member POL, a window member 20, and a cover panel CPL disposed below the display panel 10.

Examples of the display panel 10 may include an organic light emitting display panel, a micro light emitting diode (“LED”) display panel, a nano LED display panel, a quantum dot light emitting display panel, a liquid crystal display panel, a plasma display panel, a field emission display panel, an electrophoretic display panel, an electrowetting display panel, and the like. In the following description, a case where an organic light emitting display panel is applied as an embodiment of the display panel 10 will be exemplified, but the invention is not limited thereto, and other display panels may be applied within the scope of the same technical ideas.

The display panel 10 may include a first substrate 101, a second substrate 102, an active element layer ATL, and a sealing member SL.

The first substrate 101 may support the active element layer ATL disposed thereon. The first substrate 101 may be generally transparent and have high light transmittance. The first substrate 101 may include, but not limited to, an inorganic material such as glass and/or quartz, or the like. In an embodiment, the inorganic material may include, but not limited to, silicon oxide (SiO2), for example. However, without being limited thereto, the first substrate 101 may be a transparent plate or a transparent film.

The second substrate 102 may be disposed to face the first substrate 101 while being spaced apart from the first substrate 101. The second substrate 102 may protect the active element layer ATL from external moisture, air, or the like. The second substrate 102 may be generally transparent and have high light transmittance. The second substrate 102 may include, but not limited to, an inorganic material such as glass and/or quartz, or the like. In an embodiment, the inorganic material may include, but not limited to, silicon oxide (SiO2), for example. However, without being limited thereto, the second substrate 102 may be a transparent plate or a transparent film.

The first substrate 101 and the second substrate 102 may be provided to be rigid. However, the invention is not limited thereto, and in some other embodiments, the first substrate 101 and the second substrate 102 may be provided to be flexible. In this case, the first substrate 101 and the second substrate 102 may include plastic or the like.

The active element layer ATL may be disposed between the first substrate 101 and the second substrate 102. The active element layer ATL may be disposed on a top surface (or one surface) of the first substrate 101. The active element layer ATL may include a light emitting element and a thin film transistor (“TFT”) for driving the light emitting element. The second substrate 102 may be disposed above the active element layer ATL, although not limited thereto. A detailed description of the active element layer ATL will be given later.

The sealing member SL may be disposed between the first substrate 101 and the second substrate 102. In an embodiment, the sealing member SL may be disposed in the non-display area NDA of the display device 1 to surround the display area DA, for example.

The sealing member SL may bond the first substrate 101 and the second substrate 102 to each other, and may seal the active element layer ATL together with the first substrate 101 and the second substrate 102. In an embodiment, the sealing member SL may include a frit, but is not limited thereto.

An inner region of the display panel 10, which is defined by the first substrate 101, the second substrate 102, and the sealing member SL, may be disposed between the first substrate 101 and the second substrate 102. The inner region may be in a vacuum state or may be filled with gas or the like. In an embodiment, the gas may include, but not limited to, inert gas, normal atmosphere, or the like, for example. However, the inner region may be filled with not only gas but also a filler or the like.

The touch member TSP may be disposed on the display panel 10. The touch member TSP may sense a touch input. The touch member TSP may be disposed on a top surface (or one surface) of the second substrate 102. The touch member TSP may be unitary with the display panel 10 in the form of a touch layer as illustrated in the following embodiment. However, the invention is not limited thereto, and the touch member TSP may be disposed on the display panel 10 in the form of a touch panel or a touch film. The touch member TSP may include a plurality of touch electrodes. The touch member TSP may be omitted.

The anti-reflection member POL may be disposed on the touch member TSP. The anti-reflection member POL may be attached in the form of a polarizing film. The anti-reflection member POL may polarize light passing therethrough. The anti-reflection member POL may serve to reduce reflection of external light. However, without being limited thereto, the anti-reflection member POL may be laminated in the form of an anti-reflection layer inside the display panel 10. In this case, the anti-reflection member POL may include a color filter or the like for selectively transmitting light of a predetermined wavelength. Further, when the touch member TSP is omitted, the anti-reflection member POL may be attached onto the second substrate 102.

The window member 20 is disposed on the anti-reflection member POL. The window member 20 serves to cover and protect the display panel 10. The window member 20 may include a cover window 21 and a printed layer 22 disposed on the cover window 21. The window member 20 may be attached onto one surface of the display panel 10 through a transparent bonding layer TBL including an optical clear adhesive (“OCA”), an optical clear resin (“OCR”), or the like. When the display device 1 includes the anti-reflection member POL, the window member 20 may be attached onto a top surface (or one surface) of the anti-reflection member POL.

The cover window 21 may include a transparent material. The cover window 21 may include, for example, glass or plastic.

The planar shape of the cover window 21 corresponds to the shape of the display device 1 to which it is applied. In an embodiment, when the display device 1 has a substantially rectangular shape in a plan view, the cover window 21 also has a substantially rectangular shape, for example. In another embodiment, when the display device 1 has a circular shape, the cover window 21 may also have a circular shape.

The printed layer 22 may be disposed on the cover window 21. The printed layer 22 may be disposed on one surface and/or the other surface of the cover window 21. The printed layer 22 may be disposed on an edge portion of the cover window 21 and may be disposed in the non-display area NDA. The printed layer 22 may be a light blocking layer or a decorative layer providing an aesthetic appeal.

FIG. 3 is a schematic plan view showing an embodiment of an arrangement of a plurality of pixels of a display device. FIG. 4 is an enlarged view of one pixel of FIG. 3.

Referring to FIGS. 3 and 4, the display area DA of the display device 1 includes a plurality of pixels PX. The pixel PX represents the smallest unit of repetition for display. Each pixel PX may include a plurality of sub-pixels PXS. The pixels PX may be repeatedly arranged in a matrix form (in the first direction DR1 and the second direction DR2), and the sub-pixels PXS may be alternately arranged in a matrix form (in the first direction DR1 and the second direction DR2).

In order to achieve full-color display, each pixel PX may include the plurality of sub-pixels PXS (PXS_1, PXS_2, PXS_3, and PXS_4). The plurality of sub-pixels PXS (PXS_1, PXS_2, PXS_3, and PXS_4) may emit light of different colors, and at least a part thereof may emit light of the same color. In an embodiment, the first sub-pixel PXS_1 may emit light of a first color, and the second sub-pixel PXS_2 may emit light of a second color different from the first color, for example. In addition, the third sub-pixel PXS_3 and the fourth sub-pixel PXS_4 may emit light of the same color, while the third sub-pixel PXS_3 and the fourth sub-pixel PXS_4 may emit light of a third color different from the first color and the second color.

In this case, for example, in each pixel PX, the first sub-pixel PXS_1 may be responsible for emitting red light, the second sub-pixel PXS_2 may be responsible for emitting green light, and the third sub-pixels PXS_3 and the fourth sub-pixels PXS_4 may be responsible for emitting blue light, although not limited thereto. When one pixel PX includes four sub-pixels PXS_1, PXS_2, PXS_3, and PXS 4, and two sub-pixels (the third sub-pixel PXS_3 and the fourth sub-pixel PXS_4) emit blue light with a relatively short lifetime, the lifetime of the sub-pixel PXS emitting blue light may be increased.

Each pixel PX may be provided with one first sub-pixel PXS_1, one second sub-pixel PXS_2, one third sub-pixel PXS_3, and one fourth sub-pixel PXS_4. The first sub-pixel PXS_1, the second sub-pixel PXS_2, the third sub-pixel PXS_3, and the fourth sub-pixel PXS_4 may all have substantially the same shape and size as one another in a plan view, although not limited thereto. However, the invention is not limited thereto, and the first sub-pixel PXS_1, the second sub-pixel PXS_2, the third sub-pixel PXS_3, and the fourth sub-pixel PXS_4 may all have different shapes and sizes from one another in a plan view. In an alternative embodiment, a part of the sub-pixels PXS may have a different shape in a plan view, or a part of the sub-pixels PXS may have a different size in a plan view.

Each sub-pixel PXS may include an emission area EMA and a non-emission area NEM therearound. The non-emission area NEM of one sub-pixel PXS is in contact with the non-emission area NEM of an adjacent sub-pixel PXS (regardless of whether or not it is a sub-pixel PXS in the same pixel PX). The non-emission areas NEM of the adjacent sub-pixels PXS may be unitary. Further, the non-emission areas NEM of all the sub-pixels PXS may be unitary, but the invention is not limited thereto. The emission areas EMA of the adjacent sub-pixels PXS may be distinguished by the non-emission area NEM. The emission area EMA and the non-emission area NEM will be described in detail later.

Conceptually, the adjacent sub-pixels PXS may be interpreted as being in contact. Even in this case, the boundary between the sub-pixels PXS may be disposed on the non-emission areas NEM that is unitary, and thus may not be physically distinguished. The boundary between the sub-pixels PXS may be disposed at an intermediate point (or an intermediate point of the non-emission area NEM in a width direction) of a space between the emission areas EMA of the adjacent sub-pixels PXS. The overall shape of the sub-pixel PXS may be similar to that of the emission area EMA of the corresponding sub-pixel PXS, but the invention is not limited thereto.

The emission areas EMA may include first to fourth emission areas EMA1, EMA2, EMA3, and EMA4, and the sub-pixels PXS in each pixel PX may include the respective emission areas EMA (EMA1, EMA2, EMA3, and EMA4).

The emission areas EMA (EMA1, EMA2, EMA3, and EMA4) of the respective sub-pixels PXS in each pixel PX may have substantially the same shape and size as one another in a plan view. However, the invention is not limited thereto, and the emission areas EMA (EMA1, EMA2, EMA3, and EMA4) may all have different shapes and sizes from one another in a plan view. In an alternative embodiment, a part of the emission areas EMA (EMA1, EMA2, EMA3, and EMA4) may have a different shape in a plan view, or a part of the emission areas EMA (EMA1, EMA2, EMA3, and EMA4) may have a different size in a plan view.

In an embodiment, the emission area EMA (EMA1, EMA2, EMA3, EMA4) of each sub-pixel PXS may have a substantially square or rectangular shape in a plan view, although not limited thereto, for example. However, the invention is not limited thereto, and the emission area EMA (EMA1, EMA2, EMA3, EMA4) may have a polygonal shape such as a rhombus, pentagon, or hexagon in a plan view, or may have a shape such as a circle or an ellipse in a plan view. When the emission area EMA (EMA1, EMA2, EMA3, EMA4) of each sub-pixel PXS have a substantially square or rectangular shape in a plan view, each corner may have a round shape in a plan view without being limited thereto, and may have a substantially right angle.

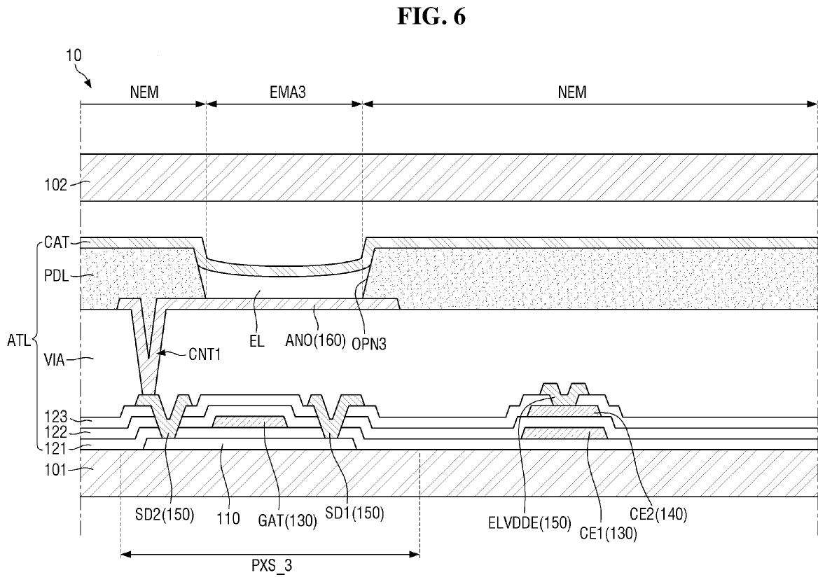

Although will be described later, a pixel defining layer PDL may be disposed on one surface of the first substrate 101. The pixel defining layer PDL may be disposed along the boundary of the sub-pixel PXS. Openings OPN (a first opening OPN1, a second opening OPN2, a third opening OPN3, and a fourth opening OPN4) exposing an anode electrode (‘ANO’ in FIG. 6) may be defined in the pixel defining layer PDL. The openings OPN1, OPN2, OPN3, and OPN4 may be disposed in the sub-pixels PXS_1, PXS_2, PXS_3, and PXS_4, respectively. The openings OPN1, OPN2, OPN3, and OPN4 may expose different regions of the anode electrode (‘ANO’ in FIG. 6).

The non-emission area NEM and the emission area EMA may be distinguished by the pixel defining layer PDL and the openings OPN (OPN1, OPN2, OPN3, and OPN4). The openings OPN1, OPN2, OPN3, and OPN4 of the sub-pixel PXS in each pixel PX may have substantially the same shape and size as one another. However, the invention is not limited thereto, and the first opening OPN1, the second opening OPN2, the third opening OPN3, and the fourth opening OPN4 may all have different shapes and sizes from one another in a plan view. In an alternative embodiment, a part of the openings OPN (OPN1, OPN2, OPN3, and OPN4) may have a different shape in a plan view, or a part of the openings OPN (OPN1, OPN2, OPN3, and OPN4) may have a different size in a plan view.

Each of the openings OPN1, OPN2, OPN3, and OPN4 of the sub-pixels PXS in each pixel PX may have a quadrangular (e.g., rectangular) or square shape. However, the invention is not limited thereto, and each of the openings OPN1, OPN2, OPN3, and OPN4 may have a polygonal shape such as a rhombus, pentagon, or hexagon in a plan view, or may have a shape such as a circle or an ellipse in a plan view. When each of the openings OPN1, OPN2, OPN3, and OPN4 of the sub-pixels PXS in each pixel PX has a substantially square or rectangular shape in a plan view, each corner may have a round shape in a plan view without being limited thereto, and may have a substantially right angle.

In the specification, the term “rectangular” or “substantially rectangular” may include not only a complete rectangle including opposite sides with parallel line segments, but also what may be viewed as a generally rectangular shape. Even when there are curves or irregularities in at least some sections of each side, it is interpreted as being included in a substantially rectangular shape when the line segments connected in the extending direction generally form a rectangular shape, for example. Further, although the extending directions of the opposite sides are not completely parallel, when their intersection angle is 15 degrees or less, or 5 degrees or less such that they are generally parallel when viewed with the naked eye, it may be interpreted as a rectangular shape. In addition, in the specification, the term “square” or “substantially square” may include not only a substantial rectangle having the same length of four sides, but also a substantial rectangle whose four sides have a substantially similar length when viewed with the naked eye even when there is a slight deviation in length of the four sides. When a deviation between the horizontal length and the vertical length of a substantial rectangle is within 10%, within 5%, or within 1%, it may be referred to as a substantial square, for example.

Each of the openings OPN1, OPN2, OPN3, and OPN4 of the sub-pixels PXS_1, PXS_2, PXS_3, and PXS_4 of each pixel PX may have a first width W1 in the first direction DR1 and a second width W2 in the second direction DR2. In the case where the first width W1 and the second width W2 of each of the openings OPN1, OPN2, OPN3, and OPN4 are substantially the same, or the first width W1 and the second width W2 are different from each other, the larger width may be about 1.2 times or less or about 1.5 times or less the smaller width. The first width W1 may refer to the width of a portion having the largest value among the widths in the first direction DR1, and the second width W2 may refer to the width of a portion having the largest value among the widths in the second direction DR2. The first width W1 and the second width W2 may pass through the center of each of the openings OPN1, OPN2, OPN3, and OPN4, but are not limited thereto.

That is, when the horizontal side (side extending in the first direction DR1) and the vertical side (side extending in the second direction DR2) of the openings OPN1, OPN2, OPN3, and OPN4 of the sub-pixels PXS_1, PXS_2, PXS_3, and PXS_4 of each pixel PX have substantially the same length in a plan view, or the horizontal side and the vertical side have different lengths, the larger length may be about 1.2 times or less or about 1.5 times or less the smaller length. That is, the length of the horizontal side may be in the range of about 0.8 times to about 1.2 times or about 0.67 times to about 1.5 times the length of the vertical side.

The following description is directed to the case where the first width W1 and the second width W2 of the openings OPN1, OPN2, OPN3, and OPN4 are substantially the same, but the invention is not limited thereto. In an embodiment, when the first width W1 is equal to or greater than the second width W2, the first width W1 may be within the range of about 1.0 times to 1.2 times, or about 1.0 times to 1.5 times the second width W2, for example. Further, when the second width W2 is equal to or greater than the first width W1, the second width W2 may be within the range of about 1.0 times to about 1.2 times, or about 1.0 times to about 1.5 times the first width W1.

When the first width W1 and the second width W2 of the openings OPN1, OPN2, OPN3, and OPN4 of the sub-pixels PXS_1, PXS_2, PXS_3, and PXS_4 are substantially the same, in-pixel uniformity (“IPU”) of a light emitting layer EL (refer to FIG. 6) disposed in each of the openings OPN1, OPN2, OPN3, and OPN4 may be improved. Accordingly, the area of a region that substantially emits light per planar area of the openings OPN1, OPN2, OPN3, and OPN4 may increase, thereby improving light efficiency of the display device 1 (refer to FIG. 1). In addition, the IPU of the light emitting layer EL (refer to FIG. 6) is improved, so that the uniformity of the luminance of light emitted from one light emitting layer EL (refer to FIG. 6) may be improved. Furthermore, the uniformity of the luminance of the display device 1 (refer to FIG. 1) may be improved.

In addition, even when the area of the sub-pixel PXS emitting blue light is increased, the sub-pixel PXS emitting blue light is divided into the third sub-pixel PXS_3 and the fourth sub-pixel PXS_4, and each of the openings OPN3 and OPN4 has a quadrangular (e.g., rectangular) or square shape, which may improve the uniformity of the light emitting layer EL of each of the sub-pixels PXS_3 and PXS_4. Accordingly, the display quality of the display device 1 (refer to FIG. 1) may be improved.

The sub-pixels PXS_1, PXS_2, PXS_3, and PXS_4 may be arranged in a matrix form. In other words, the emission areas EMA1, EMA2, EMA3, and EMA4 of the sub-pixels PXS_1, PXS_2, PXS_3, and PXS_4 may be arranged in a matrix form. A row direction may be substantially the same as the first direction DR1, and a column direction may be substantially the same as the second direction DR2. Although the following description is made in conjunction with the sub-pixels PXS_1, PXS_2, PXS_3, PXS_4, this description may also be applied to the emission areas EMA1, EMA2, EMA3, and EMA4, and further, the openings OPN1, OPN2, OPN3, and OPN4.

Sub-pixel rows RW include a first row RW1 and a third row RW3 in which the first sub-pixel PXS_1 and the second sub-pixel PXS_2 emitting light of different colors are alternately arranged, and may include a second row RW2 and a fourth row RW4 in which the third sub-pixels PXS_3 and the fourth sub-pixels PXS_4 emitting light of the same color are alternately arranged. The first to fourth rows RW1, RW2, RW3, and RW4 may be sequentially arranged repeatedly along the column direction (second direction DR2). The first row RW1 and the third row RW3 may have substantially the same array of the sub-pixels PXS_1 and PXS_2, and the second row RW2 and the fourth row RW4 may have substantially the same array of the sub-pixels PXS_3 and PXS_4.

Sub-pixel columns CL include a first column CL1 and a third column CL3 in which the first sub-pixel PXS_1 and the third sub-pixel PXS_3 emitting light of different colors are alternately arranged, and may include a second column CL2 and a fourth column CL4 in which the second sub-pixels PXS_2 and the fourth sub-pixels PXS_4 emitting light of the different colors are alternately arranged. The first to fourth columns CL1, CL2, CL3, and CL4 may be sequentially arranged repeatedly along the row direction (first direction DR1). The first column CL1 and the third column CL3 may have substantially the same array of the sub-pixels PXS_1 and PXS_3, and the second column CL2 and the fourth column CL4 may have substantially the same array of the sub-pixels PXS_2 and PXS_4.

The sub-pixels PXS_1, PXS_2, PXS_3, and PXS_4 may be arranged along the row direction (first direction DR1) and the column direction (second direction DR2). The sub-pixels PXS_1, PXS_2, PXS_3, and PXS_4 may be aligned with the sub-pixels PXS_1, PXS_2, PXS 3, and PXS_4 adjacent thereto in the row direction (first direction DR1) and the column direction (second direction DR2).

The emission areas EMA1, EMA2, EMA3, and EMA4 of the sub-pixels PXS_1, PXS_2, PXS_3, and PXS_4 belonging to each row RW1, RW2, RW3, RW4 and each column CL1, CL2, CL3, CL4 may not be arranged substantially alternately.

Specifically, an imaginary line defined between the emission areas EMA1, EMA2, EMA3, and EMA4 of the sub-pixels PXS_1, PXS_2, PXS_3, and PXS_4 adjacent to each other and extending in one of the row direction (first direction DR1) and the column direction (second direction DR2) does not traverse the emission areas EMA1, EMA2, EMA3, and EMA4 of the sub-pixels PXS_1, PXS_2, PXS_3, and PXS_4, and may extend in one of the row direction (first direction DR1) and the column direction (second direction DR2) across the emission areas EMA1, EMA2, EMA3, and EMA4 of the sub-pixels PXS_1, PXS_2, PXS_3, and PXS_4.

In an embodiment, an imaginary line defined between the first emission area EMA1 of the first sub-pixel PXS_1 of one pixel PX and the second emission area EMA2 of the second sub-pixel PXS_2 adjacent to the first sub-pixel PXS_1 and extending in the column direction (second direction DR2) may extend across a space between the third emission area EMA3 of the third sub-pixel PXS_3 of one pixel PX and the fourth emission area EMA4 of the fourth sub-pixel PXS_4 adjacent to the third sub-pixel PXS_3, and may not traverse the third emission area EMA3 and the fourth emission area EMA4, for example. Further, it may extend across a space between the first emission area EMA1 and the second emission area EMA2 and between the third emission area EMA3 and the fourth emission area EMA4 of the pixel PX adjacent to the one pixel PX, and may not traverse the emission areas EMA1, EMA2, EMA3, and EMA4 of the adjacent pixel PX.

However, the invention is not limited thereto, and the imaginary line may extend in the row direction (first direction DR1), and traverse a space between the first and third emission areas EMA1 and EMA3 and a space between the second and fourth emission areas EMA2 and EMA4.

When some of the emission areas EMA1, EMA2, EMA3, and EMA4 of the sub-pixels PXS_1, PXS_2, PXS_3, and PXS_4 of each pixel PX do not have the same shape and size as one another in a plan view, an imaginary line extending from the side of the emission areas EMA1, EMA2, EMA3, and EMA4 protruding outward in a plan view with respect to one of the row direction (first direction DR1) and the column direction (second direction DR2) may not traverse the emission areas EMA1, EMA2, EMA3, and EMA4 of the sub-pixels PXS_1, PXS_2, PXS_3, and PXS_4.

In an embodiment, when the size of the emission area EMA1 of the first sub-pixel PXS_1 of one pixel PX is larger than the size of the emission area EMA3 of the third sub-pixel PXS_3, two sides of the emission area EMA1 of the first sub-pixel PXS_1 extending in the column direction (second direction DR2) may be respectively disposed more outward in the row direction (first direction DR1) than two sides of the emission area EMA3 of the third sub-pixel PXS_3 extending in the column direction (second direction DR2), for example. In this case, the emission area EMA3 of the third sub-pixel PXS_3 may be disposed between two imaginary lines extending from two sides extending in the column direction (second direction DR2) among four sides of the emission area EMA1 of the first sub-pixel PXS_1. Further, the emission area EMA3 of the third sub-pixel PXS_3 of the pixel PX adjacent to the one pixel PX in the column direction (second direction DR2) may be disposed between the two imaginary lines. In addition, among the four sides of the emission area EMA1 of the first sub-pixel PXS_1 of the adjacent pixel PX, two sides extending in the column direction (second direction DR2) may be disposed on the two imaginary lines.

When the emission areas EMA1, EMA2, EMA3, and EMA4 of the sub-pixels PXS_1, PXS_2, PXS_3, and PXS_4 of each pixel PX have the same shape and size as one another in a plan view, one side of the emission areas EMA1, EMA2, EMA3, and EMA4 may be disposed on the same extension line as one side of the emission areas EMA1, EMA2, EMA3, and EMA4 adjacent in the extending direction of the side, and may not traverse the emission areas EMA1, EMA2, EMA3, and EMA4.

In an embodiment, one side extending in the row direction (first direction DR1) and disposed on the upper side of the plan view among the four sides of the emission area EMA1 of the first sub-pixel PXS_1 of one pixel PX and one side extending in the row direction (first direction DR1) and disposed on the upper side of the plan view among the four sides of the emission area EMA2 of the second sub-pixel PXS_2 may be disposed on the same imaginary line, for example. That is, the one side of the emission area EMA2 of the second sub-pixel PXS_2 may be disposed on an imaginary line extending from the one side of the emission area EMA1 of the first sub-pixel PXS_1. Further, one side extending in the row direction (first direction DR1) and disposed on the upper side of the plan view among the four sides of the emission area EMA1 of the first sub-pixel PXS_1 of the pixel PX adjacent to the one pixel PX in the row direction (first direction DR1) and one side extending in the row direction (first direction DR1) and disposed on the upper side of the plan view among the four sides of the emission area EMA2 of the second sub-pixel PXS_2 may be disposed on the imaginary line.

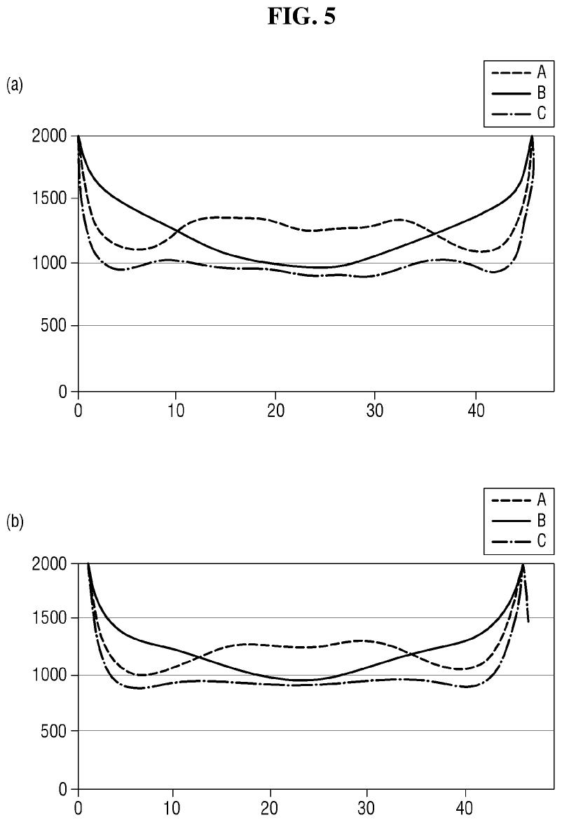

Hereinafter, this will be described with further reference to FIG. 5.

FIG. 5 is a graph showing uniformity of an embodiment of a light emitting layer of a display device. In graphs (a) and (b) of FIG. 5, an X-axis represents a width from one side to the other side with respect to the first direction DR1 and the second direction DR2, and a Y-axis represents a height.

Referring further to FIG. 5, the graph of FIG. 5 is an example and shows the height distribution of a hole injection layer of the light emitting layer EL (refer to FIG. 6) disposed in the openings OPN1, OPN2, OPN3, and OPN4. Graph (a) shows the height distribution of the hole injection layer of the light emitting layer EL (refer to FIG. 6) in cross-sectional view of the first sub-pixel PXS_1 taken in the first direction DR1, and graph (b) shows the height distribution of the hole injection layer of the light emitting layer EL (refer to FIG. 6) in cross-sectional view of the first sub-pixel PXS_1 taken in the second direction DR2, for example. Further, graphs (a) and (b) show the case where the second width W2 of the first sub-pixel PXS_1 is about 1.2 times the first width W1.

In addition, graphs (a) and (b) show a case where the hole injection layer of the light emitting layer EL (refer to FIG. 6) is dried at different temperatures. In graphs (a) and (b), line A represents a case where the hole injection layer of the light emitting layer EL (refer to FIG. 6) is dried at 35 degrees, line B represents a case where the hole injection layer of the light emitting layer EL (refer to FIG. 6) is dried at 70 degrees, and line C represents a case where the hole injection layer of the light emitting layer EL (refer to FIG. 6) is dried at 50 degrees, for example.

Referring to graphs (a) and (b), when the second width W2 of the first sub-pixel PXS_1 is about 1.2 times the first width W1, the height of the hole injection layer of the light emitting layer EL (refer to FIG. 6) dried at each temperature (A, B, C) may be substantially the same in graphs (a) and (b). In other words, as a ratio of the first width W1 to the second width W2 of the first sub-pixel PXS_1 is close to one, it may be possible to control the flow of ink printed in the first sub-pixel PXS_1, improve the uniformity of the hole injection layer of the light emitting layer EL (refer to FIG. 6) after drying, and further, improve the IPU of the light emitting layer EL (refer to FIG. 6).

In addition, the case in which the first width W1 and the second width W2 of the first sub-pixel PXS_1 have a ratio of 1:1.2 is illustrated in FIG. 5, but the invention is not limited thereto. As the ratio of the first width W1 to the second width W2 is closer to one, it may be possible to improve the uniformity of the hole injection layer of the light emitting layer EL (refer to FIG. 6), and further improve the IPU of the light emitting layer EL (refer to FIG. 6).

The foregoing description has been made in conjunction with the hole injection layer of the light emitting layer EL (refer to FIG. 6), but the invention is not limited thereto, and the above description may also be applied to an organic material layer, a hole transport layer, and/or an electron injection/transport layer of the light emitting layer EL (refer to FIG. 6).

Hereinafter, a cross-sectional view of one pixel will be described in detail.

FIG. 6 is a cross-sectional view of an embodiment of a display device. FIG. 6 shows a cross-sectional view of the third sub-pixel PXS_3.

Referring to FIGS. 4 and 6, the active element layer ATL may cover most of the regions except a partial region of the first substrate 101. The active element layer ATL may include a semiconductor layer 110, a first insulating layer 121, a first gate conductive layer 130, a second insulating layer 122, a second gate conductive layer 130, a third insulating layer 123, a data conductive layer 150, a via-layer VIA, an anode electrode ANO (or anode conductive layer 160), a pixel defining layer PDL in which an opening OPN exposing the anode electrode ANO is defined, a light emitting layer EL disposed in the opening OPN of the pixel defining layer PDL, a spacer disposed in a through hole of the pixel defining layer

PDL, and a cathode electrode CAT disposed on the light emitting layer EL, the spacer, and the pixel defining layer PDL. The layers described above may be sequentially stacked in that order. In addition, each of the layers described above may consist of a single layer, or a stack of multiple layers. Other layers may be further disposed between the layers.

The semiconductor layer 110 is disposed on the first substrate 101. The semiconductor layer 110 forms a channel of a TFT of each sub-pixel PXS. The semiconductor layer 110 may include polycrystalline silicon. However, the invention is not limited thereto, and the semiconductor layer 110 may include monocrystalline silicon, low-temperature polycrystalline silicon, amorphous silicon, or an oxide semiconductor. In an embodiment, the oxide semiconductor may include, for example, at least one of a binary compound (ABx), a ternary compound (ABxCy), or a quaternary compound (ABxCyDz) including indium, zinc, gallium, tin, titanium, aluminum, hafnium (Hf), zirconium (Zr), magnesium (Mg) and the like.

The first insulating layer 121 is disposed on the semiconductor layer 110. The first insulating layer 121 may be a gate insulating layer having a gate insulating function. The first insulating layer 121 may include a silicon compound, a metal oxide, or the like. In an embodiment, the first insulating layer 121 may include silicon oxide, silicon nitride, silicon oxynitride, aluminum oxide, tantalum oxide, hafnium oxide, zirconium oxide, titanium oxide, or the like, for example.

The first gate conductive layer 130 is disposed on the first insulating layer 121. The first gate conductive layer 130 may include a gate electrode GAT of the TFT of each sub-pixel PXS and a scan line connected thereto and a first electrode CE1 of a storage capacitor.

In an embodiment, the first gate conductive layer 130 may include at least one metal of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu).

The second insulating layer 122 may be disposed on the first gate conductive layer 130. The second insulating layer 122 may be an interlayer insulating layer or a second gate insulating layer. In an embodiment, the second insulating layer 122 may include an inorganic insulating material such as silicon oxide, silicon nitride, silicon oxynitride, hafnium oxide, aluminum oxide, titanium oxide, tantalum oxide, zinc oxide or the like.

The second gate conductive layer 140 is disposed on the second insulating layer 122. The second gate conductive layer 140 may include a second electrode CE2 of the storage capacitor. In an embodiment, the second gate conductive layer 140 may include at least one metal of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The second gate conductive layer 140 may include the same material as that of the first gate conductive layer 130, but is not limited thereto.

The third insulating layer 123 is disposed on the second gate conductive layer 140.

The third insulating layer 123 may be an interlayer insulating layer. In an embodiment, the third insulating layer 123 may include an inorganic insulating material such as silicon oxide, silicon nitride, silicon oxynitride, hafnium oxide, aluminum oxide, titanium oxide, tantalum oxide, zinc oxide or the like, for example.

The data conductive layer 150 is disposed on the third insulating layer 123. The data conductive layer 150 may include a first electrode SD1 and a second electrode SD2 of the TFT of each sub-pixel PXS. The first electrode SD1 and the second electrode SD2 of the TFT may be electrically connected to a source region and a drain region of the semiconductor layer 110 via contact holes passing through the third insulating layer 123, the second insulating layer 122 and the first insulating layer 121. A first source voltage electrode ELVDDE of each sub-pixel PXS may be provided as the data conductive layer 150. The first source voltage electrode ELVDDE may be electrically connected to the second electrode CE2 of the storage capacitor through a contact hole penetrating the third insulating layer 123.

In an embodiment, the data conductive layer 150 may include at least one metal of aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu), for example. The data conductive layer 150 may be a single layer or a multilayer. In an embodiment, the data conductive layer 150 may have a stacked structure of Ti/Al/Ti, Mo/Al/Mo, Mo/AlGe/Mo, or Ti/Cu, for example.

The via-layer VIA is disposed on the data conductive layer 150. The via-layer VIA covers the data conductive layer 150. When the via-layer VIA is provided as an organic layer, the via-layer VIA may include a substantially flat top surface although a stepped portion is provided at a lower portion thereof. In an embodiment, the via-layer VIA may include an organic insulating material including at least one of acrylic resin, epoxy resin, phenolic resin, polyamide resin, polyimide resin, unsaturated polyester resin, polyphenylene resin, polyphenylenesulfide resin and benzocyclobutene (“BCB”), for example.

The anode electrode ANO is disposed on the via-layer VIA. The anode electrode ANO may be a pixel electrode provided for each of the sub-pixels PXS_1, PXS_2, PXS_3, and PXS_4 of each pixel PX. In an embodiment, the sub-pixels PXS_1, PXS_2, PXS_3, and PXS_4 may include different anode electrodes ANO, but are not limited thereto, and at least some of the sub-pixels PXS_1, PXS_2, PXS_3, and PXS_4 may share one anode electrode ANO, for example.

The anode electrode ANO may be connected to the second electrode SD2 of the TFT through a contact hole CNT1 penetrating the via-layer VIA. The anode electrode ANO may at least partially overlap the emission area EMA of the pixel PX.

In an embodiment, the anode electrode ANO may have a stacked structure provided by stacking a material layer having a high work function, such as indium tin oxide (“ITO”), indium zinc oxide (“IZO”), zinc oxide (ZnO) and indium oxide (In2O3), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or a combination thereof, but is not limited thereto. The layer having a high work function may be disposed above the reflective material layer and disposed closer to the light emitting layer EL. The anode electrode ANO may have a multilayer structure such as ITO/Mg, ITO/MgF, ITO/Ag and ITO/Ag/ITO, but is not limited thereto.

The pixel defining layer PDL may be disposed on the anode electrode ANO. The pixel defining layer PDL may include an organic insulating material or an inorganic insulating material. In an embodiment, the pixel defining layer PDL may include at least one of polyimide resin, acrylic resin, a silicon compound, or polyacrylic resin, for example.

The light emitting layer EL is disposed on the anode electrode ANO exposed by the pixel defining layer PDL. The light emitting layer EL may include an organic material layer. The organic material layer of the light emitting layer may include an organic light emitting layer, and may further include a hole injection/transport layer and/or an electron injection/transport layer. The light emitting layer EL may be provided by inkjet printing, and thus the top surface of the light emitting layer EL may have a downwardly concave shape in cross-sectional view, although not limited thereto. In other words, a thickness of the light emitting layer EL may be increased toward the pixel defining layer PDL side. In other words, the thickness of the light emitting layer EL may be increased from a central portion of the light emitting layer EL toward an outer side (the pixel defining layer side) in a plan view.

The cathode electrode CAT may be disposed on the light emitting layer EL. The cathode electrode CAT may cover the light emitting layer EL and may be disposed on the pixel defining layer PDL. The cathode electrode CAT may be a common electrode extended across all the pixels. The cathode electrode CAT may be conformably provided along the lower structure to reflect the stepped portions of the lower structure. The anode electrode ANO, the light emitting layer EL, and the cathode electrode CAT may constitute an organic light emitting element.

The cathode electrode CAT may include a material layer having a low work function, such as Li, Ca, LiF/Ca, LiF/Al, Al, Mg, Ag, Pt, Pd, Ni, Au Nd, Ir, Cr, BaF, Ba or a compound or combination thereof (e.g., a combination of Ag and Mg). The cathode electrode CAT may further include a transparent metal oxide layer disposed on the material layer having a low work function.

A second substrate 102 is disposed on the cathode electrode CAT. The cathode electrode CAT and the second substrate 102 may be in direct contact with each other, but the invention is not limited thereto.

In addition, although not shown, a spacer (not shown) may be further disposed on the pixel defining layer PDL. The spacer (not shown) may serve to maintain a gap with a structure disposed thereabove. In an embodiment, in the case of depositing an organic material of the light emitting layer EL through a fine metal mask, the spacer (not shown) may serve to prevent the fine metal mask from sagging, for example. In some cases, the spacer (not shown) may serve to support a structure laminated thereon, to maintain a cell gap between the first substrate 101 and the second substrate 102, and to mitigate deformation caused by stress when the display panel 10 is pressed.

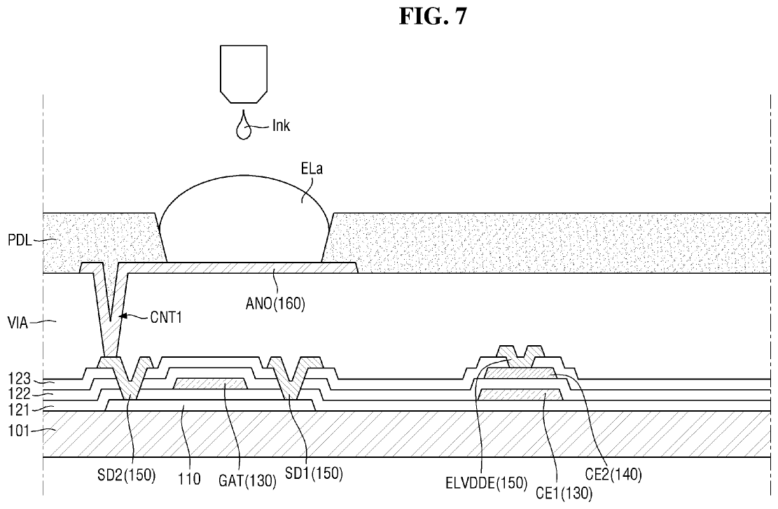

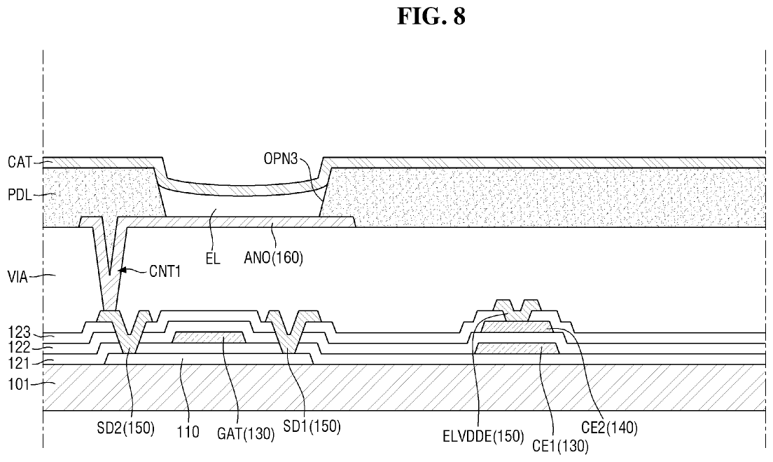

Hereinafter, a method of manufacturing a display device in an embodiment will be described with reference to FIGS. 7 and 8. Since a method of forming the components of the TFT disposed on the first substrate 101, the via-layer VIA, and the anode electrode ANO and the pixel defining layer PDL is a well-known technique, a detailed description thereof will be omitted in this specification.

FIGS. 7 to 8 are cross-sectional views illustrating an embodiment of a method of manufacturing a display device.

First, referring to FIGS. 7 and 8, the light emitting layer EL is provided through ink-jet printing, and the cathode electrode CAT covering the light emitting layer EL and the pixel defining layer PDL is provided.

Specifically, a light emitting layer material layer ELa is disposed on the anode electrode ANO exposed by the pixel defining layer PDL. Since the pixel defining layer PDL has liquid repellency, a surface bonding force between light emitting layer material layer Ela and the pixel defining layer PDL is low, which makes it possible to increase a contact angle between the light emitting layer material layer ELa and the pixel defining layer PDL. Therefore, the light emitting layer material layer Ela does not overflow onto the top surface of the pixel defining layer PDL, and may be more stably disposed on the anode electrode ANO exposed by the pixel defining layer PDL.

The light emitting layer material layer ELa may be injected in the form of ink by an inkjet printing device (or a liquid droplet injection device), and may be disposed on the anode electrode ANO exposed by the pixel defining layer PDL, although not limited thereto. Accordingly, even in a high-resolution display device, the light emitting layer EL may be provided at a desired position more accurately.

After the light emitting layer material layer ELa is inkjet-printed, the light emitting layer material layer ELa is dried to form the light emitting layer EL. A solvent of the light emitting layer material layer ELa may evaporate by the drying process, and a volume of the light emitting layer material layer ELa is reduced to form the light emitting layer EL shown in FIG. 8. The injection amount of the light emitting layer material layer ELa may be determined in consideration of a surface tension and the amount of volume reduction after the drying.

The light emitting layer material layer ELa printed by the inkjet printing device may include two or more solvents having different vapor pressures. That is, the solvent of the light emitting layer material layer ELa printed by the inkjet printing device may be a solvent in which the first solvent and the second solvent are mixed. In an embodiment, the light emitting layer material layer ELa may include a first solvent and a second solvent, the vapor pressure of the first solvent may be less than that of the second solvent, and the vapor pressure of the first solvent may be about 10-3 torr or less, for example.

In an embodiment, the vapor pressure of the first solvent may be in at least one of the ranges of about 10⁻⁵ torr to about 10⁻³ torr, about 10⁻⁶ torr to about 10⁻³ torr, and about 4×10⁻⁴ torr to about 6×10⁻⁴ torr, or may be about 5.07×10⁻⁴ torr, although not limited thereto, for example. In addition, the vapor pressure of the first solvent may be greater than about 10⁻³ torr. Although not limited to the following, for example, the vapor pressure of the first solvent may be in at least one of the ranges of about 10⁻³ torr to about 10⁻² torr, and about 10⁻³ torr to about 10⁻¹ torr, or may be about 2.29×10⁻² torr.

In this case, the light emitting layer material layer ELa may be provided more uniformly. When the light emitting layer material layer ELa printed by the inkjet printing device includes a first solvent and a second solvent having different vapor pressures, a solvent (the second solvent) having a relatively high vapor pressure may evaporate first, and then a solvent (the first solvent) having a relatively low vapor pressure may evaporate.

In other words, in the process of reducing the volume of the light emitting layer material layer ELa by drying, from immediately after printing the light emitting layer material layer ELa until the upper portion of the light emitting layer material layer ELa reaches the height of the top surface of the pixel defining layer PDL, the solvent (second solvent) having a relatively high vapor pressure may preferentially evaporate. Thereafter, when the upper portion of the light emitting layer material layer ELa is disposed at a height lower than the top surface of the pixel defining layer PDL, the first solvent having a relatively low vapor pressure may mainly remain. Accordingly, the flow of the light emitting layer material layer ELa may be controlled according to the drying conditions, and after drying of the light emitting layer material layer ELa is completed, the uniformity of the thickness of the light emitting layer EL may be improved.

As shown in FIG. 4, the first width W1 of each of the openings OPN1, OPN2, OPN3, and OPN4 of the respective sub-pixels PXS may be within the range of about 0.8 times to about 1.2 times or about 0.67 times to about 1.5 times the second width W2, and when the light emitting layer material layer ELa is printed by the inkjet printing device, the flow of the light emitting layer material layer ELa that may occur during drying may be controlled.

Specifically, the light emitting layer material layer ELa printed by the inkjet printing device may flow during drying, and drying may proceed faster in a portion having a large surface area. That is, in the openings OPN1, OPN2, OPN3, and OPN4 of the respective sub-pixels PXS, the light emitting layer material layer ELa adjacent to the relatively long side may be dried faster than the light emitting layer material layer ELa adjacent to the relatively short side in a plan view. However, when the first width W1 and the second width W2 of each of the openings OPN1, OPN2, OPN3, and OPN4 of the respective sub-pixels PXS are within the above range, the rate at which the light emitting layer material layer ELa adjacent to each side is dried may be substantially the same. Accordingly, it may be possible to suppress or prevent a decrease in the uniformity of the light emitting layer EL that may occur due to a difference in drying rate of each area of the light emitting layer material layer ELa disposed in the openings OPN1, OPN2, OPN3, and OPN4 of the respective sub-pixels PXS, thereby improving the uniformity of the light emitting layer EL.

In addition, in the case where the first width W1 and the second width W2 of each of the openings OPN1, OPN2, OPN3, and OPN4 of the respective sub-pixels PXS are within the above range, although the drying rate of the light emitting layer material layer ELa adjacent to each side is not substantially the same, it may be possible to reduce a difference in drying rate of each area, and to suppress or prevent a decrease in the uniformity of the light emitting layer EL, thereby improving the uniformity of the light emitting layer EL.

After the light emitting layer EL is provided, the cathode electrode CAT shown in FIG. 8 may be provided. The cathode electrode CAT may be disposed on the entire via-layer VIA while covering the anode electrode ANO, the spacer, the pixel defining layer PDL, and the light emitting layer EL.

Although not illustrated, after the cathode electrode CAT is provided, a second substrate (‘102’ in FIG. 6) may be disposed on the cathode electrode CAT.

Hereinafter, other embodiments will be described. In the following embodiments, a description of the same components as those of the above-described embodiment will be omitted or simplified, and differences will be mainly described.

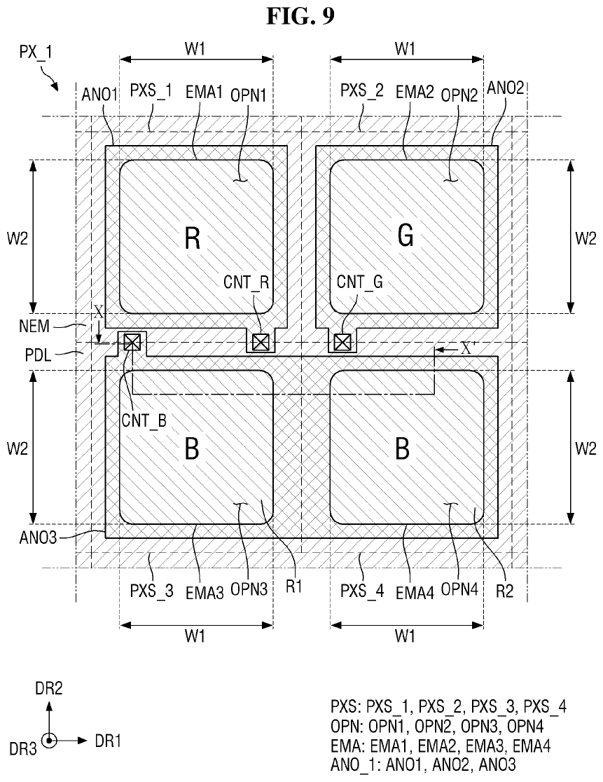

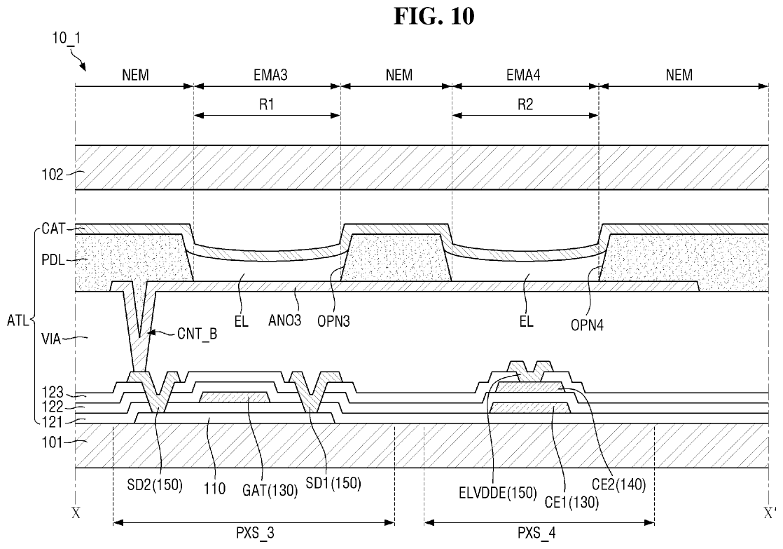

FIG. 9 is an enlarged view of another embodiment of one pixel of a display device. FIG. 10 is a cross-sectional view taken along line X-X′ of FIG. 9. FIG. 9 illustrates not only the pixel defining layer PDL but also an anode electrode layer ANO_1 in the illustrated embodiment.

Referring to FIGS. 9 and 10, at least some of the sub-pixels PXS of one pixel PX_1 in the illustrated embodiment may share one of anode electrodes ANO1, ANO2, and ANO3. That is, different regions of the anode electrode layer ANO_1 exposed by at least two of the openings OPN2, OPN2, OPN3, and OPN4 may be unitary or electrically connected.

Specifically, the anode electrode layer ANO_1 in the illustrated embodiment may include a first anode electrode ANO1, a second anode electrode ANO2, and a third anode electrode ANO3. The first anode electrode ANO1, the second anode electrode ANO2, and the third anode electrode ANO3 may be separated from each other and spaced apart from each other.

The first anode electrode ANO1 may be electrically connected to the TFT therebelow through a contact hole CNT_R, the second anode electrode ANO2 may be electrically connected to the TFT therebelow through a contact hole CNT_G, and the third anode electrode ANO3 may be electrically connected to the TFT therebelow through a contact hole CNT_B.

The first anode electrode ANO1 may overlap the first emission area EMA1 of the first sub-pixel PXS_1, and may be exposed by the first opening OPN1 of the first sub-pixel PXS_1. The second anode electrode ANO2 may overlap the second emission area EMA2 of the second sub-pixel PXS_2, and may be exposed by the second opening OPN2 of the second sub-pixel PXS_2.

The third anode electrode ANO3 may overlap the third emission area EMA3 of the third sub-pixel PXS_3 and the fourth emission area EMA4 of the fourth sub-pixel PXS_4, and may be exposed by the third opening OPN3 of the third sub-pixel PXS_3 and the fourth opening OPN4 of the fourth sub-pixel PXS_4. That is, the third anode electrode ANO3 may expose different regions R1 and R2 by the third opening OPN3 and the fourth opening OPN4 separated from each other.

The third opening OPN3 may expose the first region R1 of the third anode electrode ANO3, and the fourth opening OPN4 may expose the second region R2 of the third anode electrode ANO3. The first region R1 and the second region R2 of the third anode electrode ANO3 may be unitary and may be electrically connected to each other.

The light emitting layer EL may be disposed on the first region R1 of the third anode electrode ANO3 exposed by the third opening OPN3 and the second region R2 of the third anode electrode ANO3. The light emitting layer EL disposed on the first region R1 of the third anode electrode ANO3 and the light emitting layer EL disposed on the second region R2 of the third anode electrode ANO3 may be separated from each other. Although not limited to the following, the light emitting layer EL disposed on the first region R1 of the third anode electrode ANO3 and the light emitting layer EL disposed on the second region R2 of the third anode electrode ANO3 may emit light of the same color. In an embodiment, the light emitting layer EL disposed on the first region R1 of the third anode electrode ANO3 and the light emitting layer EL disposed on the second region R2 of the third anode electrode ANO3 may emit blue light, for example.

Even in this case, when the first width W1 and the second width W2 of each of the openings OPN1, OPN2, OPN3, and OPN4 of the respective sub-pixels PXS are substantially the same, or the first width W1 and the second width W2 have different sizes from each other, the larger width may have a size of about 1.2 times or less or about 1.5 times or less the smaller width. Accordingly, it may be possible to improve the uniformity of the light emitting layer EL disposed in each of the openings OPN1, OPN2, OPN3, and OPN4, and improve the light efficiency and luminance uniformity of the display device 1 (refer to FIG. 1), and the display quality may be improved.

In addition, as different sub-pixels PXS_3 and PXS_4 emitting light of the same color share one anode electrode ANO3, even when light of the same color is emitted from the different sub-pixels PXS_3 and PXS_4, there is no difference in the reaction speed of the sub-pixels PXS_3 and PXS_4 of one pixel PX_1, and light may be emitted at substantially the same timing. Accordingly, a desired color of each pixel PX_1 may be more clearly expressed, and the display quality of the display device 1 (refer to FIG. 1) may be improved.

In the above, it has been described that the third sub-pixel PXS_3 and the fourth sub-pixel PXS_4 emit blue light and share one anode electrode ANO3, but the invention is not limited thereto. In some embodiments, the third sub-pixel PXS_3 and the fourth sub-pixel PXS_4 may emit any one of white, red, and green light while sharing one anode electrode ANO3.

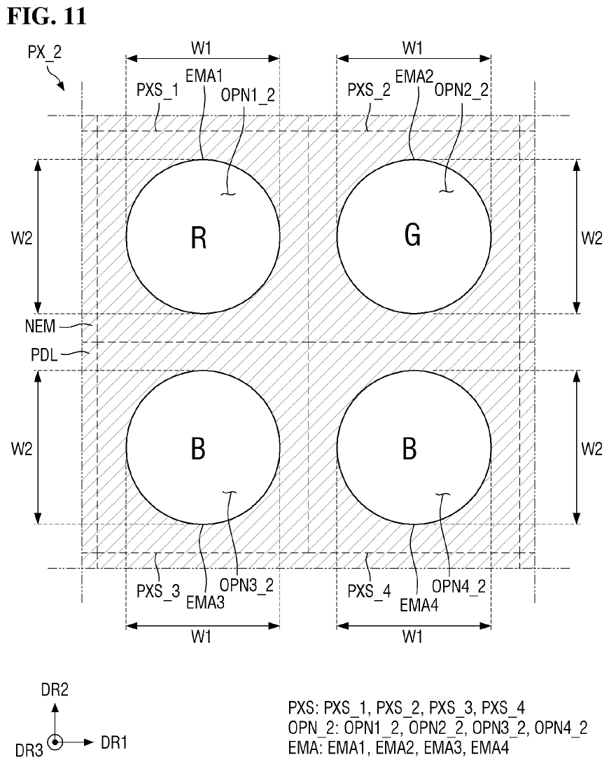

FIG. 11 is an enlarged view of another embodiment of one pixel of a display device.

Referring to FIG. 11, the illustrated embodiment is different from the embodiment of FIG. 4 in that the sub-pixels PXS (PXS_1, PXS_2, PXS_3, and PXS_4) of one pixel PX_2 have a circular or elliptical shape in a plan view.

Specifically, the openings OPN1_2, OPN2_2, OPN3_2, and OPN4_2 of the respective sub-pixels PXS (PXS_1, PXS_2, PXS_3, and PXS_4) may have a first width W1 that is a width in the first direction DR1 and a second width W2 that is a width in the second direction DR2. When the first width W1 and the second width W2 are substantially the same, the openings OPN1_2, OPN2_2, OPN3_2, and OPN4_2 of the respective sub-pixels PXS (PXS_1, PXS_2, PXS_3, and PXS_4) may have a substantially circular shape in a plan view. In addition, when the first width W1 and the second width W2 have different sizes from each other, the larger width may have a size of about 1.2 times or less or about 1.5 times or less the smaller width. In this case, the openings OPN1_2, OPN2_2, OPN3_2, and OPN4_2 of the respective sub-pixels PXS (PXS_1, PXS_2, PXS_3, and PXS_4) may have a substantially elliptical shape in a plan view.

Even in this case, it may be possible to improve the uniformity of the light emitting layer EL disposed in each of the openings OPN1_2, OPN2_2, OPN3_2, and OPN4_2, and improve the light efficiency and luminance uniformity of the display device 1 (refer to FIG.

1), and the display quality may be improved.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

What is claimed is:

1. A display device comprising:
a substrate;
a first pixel electrode disposed on the substrate, and including a first region and a second region electrically connected to each other without overlapping each other;
a pixel defining layer disposed on the substrate on which the first pixel electrode is disposed, the pixel defining layer defining:
a first opening penetrating the pixel defining layer in a thickness direction and exposing the first region of the first pixel electrode; and
a second opening penetrating the pixel defining layer in the thickness direction, exposing the second region of the first pixel electrode, and separated from the first opening; and
a light emitting layer disposed in the first opening exposing the first region of the first pixel electrode and the second opening exposing the second region of the first pixel electrode.

2. The display device of claim 1, wherein in a plan view, the first opening and the second opening have a first width which is a width in a first direction and a second width which is a width in a second direction perpendicular to the first direction, and the first width is in a range of about 0.8 times to about 1.2 times the second width.

3. The display device of claim 1, further comprising a second pixel electrode and a third pixel electrode disposed on the substrate and separated and spaced apart from the first pixel electrode,
wherein the pixel defining layer further defines a third opening penetrating in the thickness direction and exposing the second pixel electrode, and a fourth opening exposing the third pixel electrode, and
the light emitting layer is further disposed on the second pixel electrode exposed by the third opening and the third pixel electrode exposed by the fourth opening.

4. The display device of claim 3, wherein the light emitting layer disposed in the first opening and the light emitting layer disposed in the second opening emit light of the same color.

5. The display device of claim 4, wherein the light emitting layer disposed in the third opening and the light emitting layer disposed in the fourth opening emit light of different colors, and emit light of a different color from that of the light emitting layer disposed in the first and second openings.

6. The display device of claim 5, wherein the light emitting layer disposed in the first opening and the second opening emits blue light, the light emitting layer disposed in the third opening emits red light, and the light emitting layer disposed in the fourth opening emits green light.

7. The display device of claim 1, wherein the first opening and the second opening have the same shape and size as each other in a plan view.

8. The display device of claim 7, wherein the first opening and the second opening have a square or circular shape in the plan view.

9. A display device comprising:
a substrate;
an anode conductive layer disposed on the substrate;
a pixel defining layer disposed on the substrate on which the anode conductive layer is disposed, the pixel defining layer defining a first opening, a second opening, a third opening, and a fourth opening penetrating the pixel defining layer in a thickness direction and respectively exposing different regions of the anode conductive layer; and
a light emitting layer disposed in the first opening, the second opening, the third opening, and the fourth opening exposing different regions of the anode conductive layer,
wherein in a plan view, the first opening, the second opening, the third opening, and the fourth opening have a first width which is a width in a first direction and a second width which is a width in a second direction perpendicular to the first direction, and the first width is in a range of about 0.8 times to about 1.2 times the second width.

10. The display device of claim 9, wherein the anode conductive layer includes a first pixel electrode, a second pixel electrode, and a third pixel electrode separated from each other,
the third pixel electrode includes a first region and a second region electrically connected to each other without overlapping each other,
the first opening exposes the first pixel electrode, the second opening exposes the second pixel electrode, the third opening exposes the first region of the third pixel electrode, and the fourth opening exposes the second region of the third pixel electrode.

11. The display device of claim 10, wherein the light emitting layer disposed in the third opening and the light emitting layer disposed in the fourth opening emit light of the same color.

12. The display device of claim 9, wherein the first opening, the second opening, the third opening, and the fourth opening have the same shape and size as one another in the plan view.

13. The display device of claim 12, wherein the first opening, the second opening, the third opening, and the fourth opening have a square or circular shape in the plan view.

14. A display device comprising a plurality of first sub-pixels, a plurality of second sub-pixels, a plurality of third sub-pixels, and a plurality of fourth sub-pixels,
wherein the first sub-pixel, the second sub-pixel, and the third sub-pixel emit light of different colors, and the fourth sub-pixel emit light of the same color as the third sub-pixel,
wherein the plurality of first sub-pixels and the plurality of second sub-pixels are alternately arranged along a first direction and form first rows, the plurality of third sub-pixels and the plurality of fourth sub-pixels are alternately arranged along the first direction and form second rows, and the first rows and the second rows are alternately arranged,
wherein the plurality of first sub-pixels and the plurality of third sub-pixels are alternately disposed along a second direction perpendicular to the first direction and form first columns, the plurality of second sub-pixels and the plurality of fourth sub-pixels are alternately disposed along the second direction and form second columns, and the first columns and the second columns are alternately arranged,
wherein each of the plurality of first sub-pixels includes a first emission area, each of the plurality of second sub-pixels includes a second emission area, each of the plurality of third sub-pixels includes a third emission area, and each of the plurality of fourth sub-pixels includes a fourth emission area, and
wherein the first emission area, the second emission area, the third emission area, and the fourth emission area have the same shape in a plan view.

15. The display device of claim 14, wherein an imaginary extension line disposed between the first emission area and the second emission area and extending in the second direction extends across a space between the third emission area and the fourth emission area adjacent to the first emission area and the second emission area.

16. The display device of claim 14, wherein the first sub-pixel, the second sub-pixel, the third sub-pixel, and the fourth sub-pixel constitute a pixel which is a minimum unit for displaying an image.

17. The display device of claim 16, wherein the first sub-pixel emits red light, the second sub-pixel emits green light, and the third sub-pixel and the fourth sub-pixel emit blue light.

18. The display device of claim 14, wherein in the plan view, each of the first emission area, the second emission area, the third emission area, and the fourth emission area has a first width which is a width in the first direction and a second width which is a width in the second direction, and the first width is in a range of about 1.0 times to about 1.2 times the second width.

19. The display device of claim 18, wherein each of the first emission area, the second emission area, the third emission area, and the fourth emission area has one of a rectangular shape, a square shape, an elliptical shape, and a circular shape in the plan view.

20. The display device of claim 14, wherein the first sub-pixel emits red light, the second sub-pixel emits green light, and the third and fourth sub-pixels emit blue light.
